(19) United States
(12) Patent Application Publication
(10) Pub. No.: US 2007/0168839 A1
(43) Pub. Date: Jul. 19, 2007

(54) Interface apparatus for connecting a device and a host system, and method of controlling the interface apparatus

(75) Inventors: Shinji Kunishige, Kokubunji-shi (JP); Yuuko Maki, Iruma-shi (JP); Shuichi Ishii, Ome-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/476,930

(22) Filed: Jun. 29, 2006

(30) Foreign Application Priority Data
Jun. 30, 2005 (JP) 2005-191213

(51) Int. Cl. G11C 29/00

(52) U.S. Cl. 714/770

(57) ABSTRACT

According to one embodiment, a serial ATA interface apparatus having an S-ATA bridge. The S-ATA bridge is to be connected to a host system by a serial ATA bus. The S-ATA bridge has a shadow register and a buffer memory. The shadow register stores commands. The buffer memory can access a HDC. The S-ATA bridge finishes processing the commands before it outputs a response signal to the host system.

### CROSS-REFERENCE TO RELATED APPLICATIONS

This application is based upon and claims the benefit of priority from Japanese Patent Application No. 2005-191213, filed Jun. 30, 2005, the entire contents of which are incorporated herein by reference.

### BACKGROUND

1. Field

One embodiment of the present invention relates generally to an interface apparatus of serial ATA type, and particularly to an interface apparatus that is improved in terms of the speed of data transfer between a host system and a device.

2. Description of the Related Art

In recent years, serial ATA interfaces (i.e., interfaces that accord with the Serial AT Attachment Standards) have attracted attention as interface that connects a host system such as a personal computer and a device such as a hard disk drive (hereinafter referred to as disk drive). Note that serial ATA may herein be referred to as S-ATA.

The conventional disk drive incorporates a disk controller that implements interface of the parallel ATA interface specification, between a disk drive and a host system. The disk drive therefore needs to have an interface converter such as an S-ATA bridge that employs a serial ATA interface to process native command queuing (NCQ) commands. (See, for example, Jpn. Pat. Appln. KOKAI Publication No. 2003-223411.)

As mentioned above, a disk drive can have a serial ATA interface by using an interface converter such as an S-ATA bridge. More specifically, it can have a serial ATA interface if it has a system LSI that incorporates an S-ATA bridge and a hard disk controller (HDC).

In such a system LSI, the following sequence of steps must be carried out to process NCQ commands. That is, the S-ATA bridge receives a register-host to drive (RegH/D) command (FPDMAQ command) from the host system and stores the command temporarily in a shadow register of the ATA specification.

Next, the S-ATA bridge transfers the command stored in the shadow register to the task file registers of the HDC (e.g., command registers), which are connected by an parallel ATA interface. The HDC registers command and transfers the content (e.g., status) of the task file register to the shadow register. After this sequence of steps is completed, the S-ATA bridge outputs a RegD/H (register-device to host) command to the host system, informing that the command has been received.

In this sequence of steps, however, about 40 μs elapses between the time the S-ATA bridge receives a command from the host system and the time it responds to the host system. This inevitably results in a decrease of the speed of data transfer between the host system and the disk drive.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a block diagram showing a system configuration related to an embodiment of the present invention:

FIG. 2 is a perspective view of a personal computer related to the embodiment of the invention;

FIG. 3 is a diagram explaining the structural concept of an S-ATA bridge according to the embodiment of the invention:

FIG. 4 is a flowchart explaining the sequence of processing a command in the embodiment of this invention;

FIG. 5 and FIG. 6 are timing charts explaining how two read commands are processed in the embodiment of this invention; and

FIG. 7 and FIG. 8 are timing charts explaining how two write commands are processed in the embodiment of the present invention.

### DETAILED DESCRIPTION

An embodiment according to the present invention will be described, with reference to the accompanying drawings.

This embodiment is a serial ATA interface that can shorten the response time that elapses from the receipt of a command and the responding to the command, ultimately increasing the speed of data transfer between a host system and a device.

In general, according to one embodiment of the invention, there is provided a serial ATA interface apparatus for connecting a host system and a device. The serial ATA interface apparatus comprises a register which stores commands transmitted from the host system via a serial ATA bus, a transmission unit which transmits an interruption signal to a controller provided in the device through a parallel ATA bus, the interruption signal being stored in the register and indicating that the transmission unit has received a command, a memory which stores the commands transferred from the register and which can be accessed by the controller, and an output unit which checks the commands stored in the register and which outputs a response signal to the host system through the serial ATA bus when the commands are found to be correct.

[System Configuration]

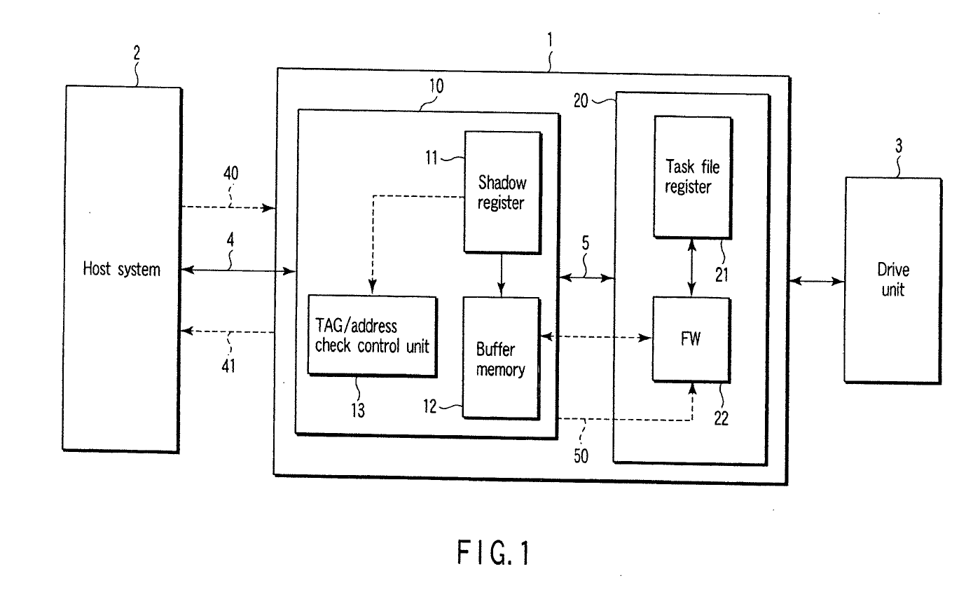

According to an embodiment, FIG. 1 shows the configuration of a system that includes an interface.

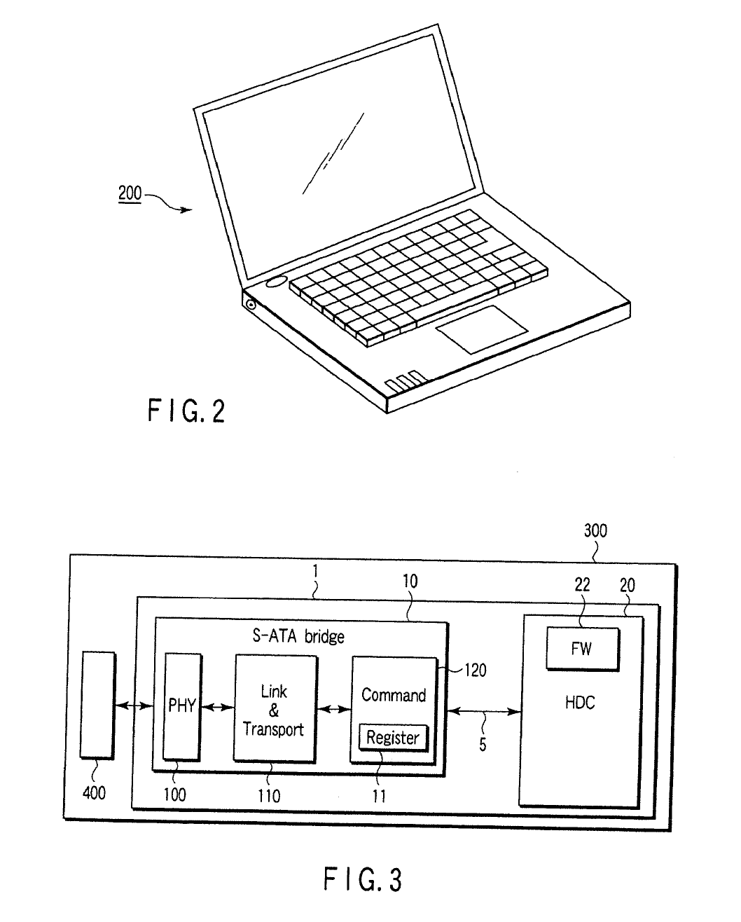

The system comprises a serial ATA interface unit 1, a host system 2, and a disk drive. The serial ATA interface unit 1 connects the host system 2 and a disk drive unit 3 of the disk drive. The host system 2 is, for example, a personal computer 200 shown in FIG. 2. The disk drive is, for example, the hard disk drive incorporated in the personal computer 200. The drive unit 3 includes a disk-shaped medium and a head and can record data on, and reproduce data from, the disk-shaped medium.

As FIG. 1 shows, The disk drive includes the drive unit 3 and the interface unit 1 constructed from a system LSI. The interface unit 1 incorporates an S-ATA bridge 10 and a hard disk controller (HDC) 20. The S-ATA bridge 10 is an interface converter. The HDC 20 performs the drive-interface function of controlling the data transfer (read/write) between the S-ATA bridge 10 and the disk drive 3. A parallel ATA bus 5 connects the HDC 20 to the S-ATA bridge 10.

The HDC 20 includes a task register file 21 and firmware (FW) 22. The task file register 21 stores commands issued from the host system 2. The FW 22 processes the commands read from the task file register 21. The task register file 21 is a group of registers such as command registers for storing commands to be executed.

(Configuration of the S-ATA Bridge 10)

The S-ATA bridge 10 is connected to the host system 2 by a serial ATA bus 4, and to the HDC 20 by a parallel ATA bus 5. The S-ATA bridge 10 includes an S-ATA shadow register 11, a buffer memory 12, and a TAG/address check control unit 13.

The shadow register 11 stores command one after another, which have been sent from the host system 2 through the serial ATA bus 4. The buffer memory 12 stores the content (i.e., commands) transferred from the shadow register 11. The buffer memory 12 can be accessed by the HDC 20 via the parallel ATA bus 5.

The TAG/address check control unit 13 is hardware that determines whether the TAG number and LBA (logic-block address) of each command stored in the shadow register 11 are correct or not. The TAG numbers are identifiers of the commands sequentially sent from the host system 2, and are used to manage the execution of these commands.

FIG. 3 is a diagram showing a circuit board 300, on which a system LSI and a serial ATA interface 400 are mounted. The circuit board 300 is incorporated in the disk drive. The serial ATA interface 400 is connected to the microprocessor (CPU) of the personal computer 200 that is the host system 2. As mentioned above, the HDC 20 is connected to the disk drive unit 3.

As FIG. 3 shows, the S-ATA bridge 10 has, in concept, a physical (PHY) layer 100, a link/transport (Link & Transport) layer 110, and a command layer 120. The physical layer 100 is connected to the serial ATA interface 400. The link/transport layer 110 exchanges data with the physical layer 100.

The command layer 120 includes the shadow register 11 described above. The S-ATA bridge 10 is connected to the HDC 20 not only by the parallel ATA bus 5, but also by an interface-signal line (IF-REG).

[Operating]

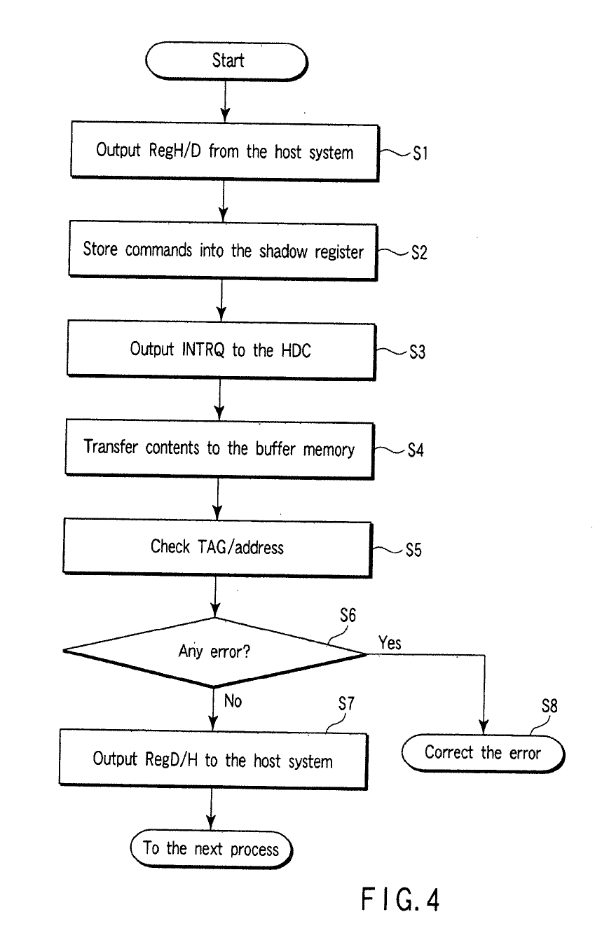

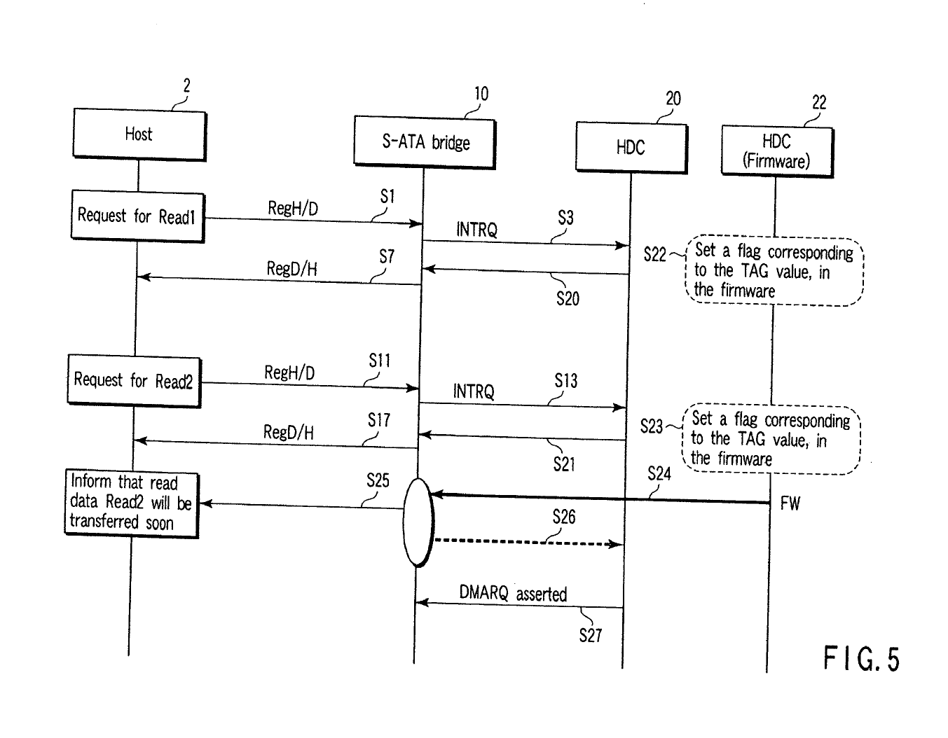

The sequence of processing NCQ commands in the present embodiment will be described, with reference to the flowchart of FIG. 4.

First, the S-ATA bridge 10 receives RegH/D (register-host to device) commands (FDMAQ commands) 40 of the S-ATA specification from the host system 2 through the serial ATA bus 4 (Step S1). The S-ATA bridge 10 stores these ATA commands (e.g., read command and write command) sequentially into the shadow register 11 (Step S2).

When the command register included in the shadow register 11 is updated, the S-ATA bridge 10 outputs signal (INTRQ) 50 to the FW 22 provided in the HDC 20 (Step S3). From the interruption signal 50, the FW 22 determines the receipt of NCQ commands from the host system 2.

When the command register is updated, the S-ATA bridge 10 transfers all contents in the shadow register 11 to the buffer memory 12 (Step S4). When the command register is further updated, the TAG/address check control unit 13 of the S-ATA bridge 10 checks the TAG number and LAB address stored in the shadow register 11 (Step S5) and determines whether the TAG number and the LAB address are incorrect (Steps S5 and S6).

If the TAG/address check control unit 13 determines that the TAG number and the LAB address are correct (if NO in Step S6), the ATA bridge 10 set the busy bit to 0 as will be described later and output an RegH/D (register-host to device) command 41, thus informing that the command has been received (Step S7). If the TAG/address-check control unit 13 determines that the TAG number and the LAB address are incorrect (if YES in Step S6), a process of correcting errors is carried out (Step S8).

The sequence of the steps described above is repeated, thereby receiving the NCQ commands (ATA commands) continuously sent from the host system 2 can be received, one after another.

In the HDC 20, the FW 22 accesses the buffer memory 12 upon receiving an interruption signal (INTRQ) 50. Thus, the HDC 20 acquires all contents of the shadow register 11 and stores the contents into the task file register 21.

The HDC 20 executes the commands that the FW 22 has stored into the command register of the task file register 21, thus performing a control in order to record data on, or reproduce data from, the disk-shaped medium. That is, the HDC 20 performs a control to execute, for example, a read command supplied from the host system 2, to receive read data from the disk drive unit 3 and to transfer the read data to the host system 2. Further, the HDC 20 performs a control to execute, for example, a write command supplied from the host system 2, to receive write data from the host system 2 and to transfer the read data to the disk drive unit 3.

The S-ATA bridge 10 thus performs the process of receiving NCQ (ATA) commands from the host system 2 through the serial ATA interface. In this embodiment, the S-ATA bridge 10 does not transfer all contents of the shadow register 11 to the task file register 21 of the HDC 20, but the contents of the shadow register 11 are transferred to the buffer memory 12 provided in the S-ATA bridge 10. The FW 22 of the HDC 20 accesses the buffer memory 12 of the S-ATA bridge 10. The contents of the shadow register 11 of the S-ATA bridge 10 are thereby stored into the task file register 21 of the HDC 20.

If the TAG/address check control unit 13 determines that the TAG number and the LAB address are correct, the S-ATA bridge 10 informs the host system 2 that the commands have been received. Hence, in the present embodiment, the S-ATA bridge 10 alone performs all steps, first receiving commands from the host system 2 and finally responding to the host system 2, without transferring data between the shadow register 11 and the HDC 20. The time required to performing all steps can therefore be greatly shortened, by the time for transferring data between the shadow register 11 and the task file register 21. This can increase the speed of transferring data between the host system 2 and the disk drive unit 3 as the commands are executed after the S-ATA bridge 10 has receives commands from the host system 2 and executed these command.

(Example of the Command Processing)

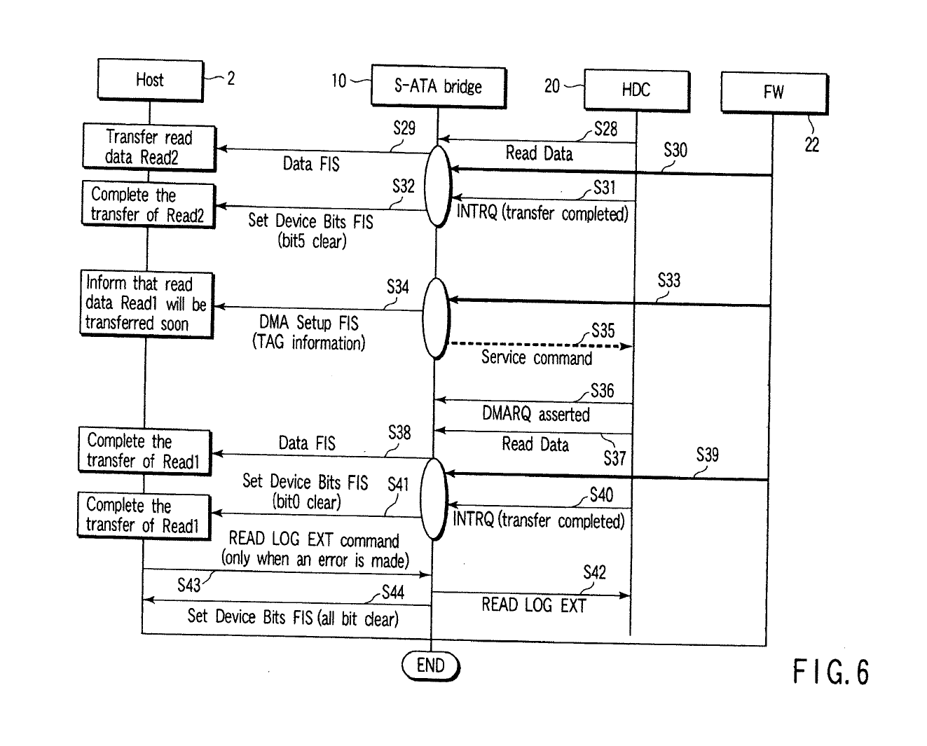

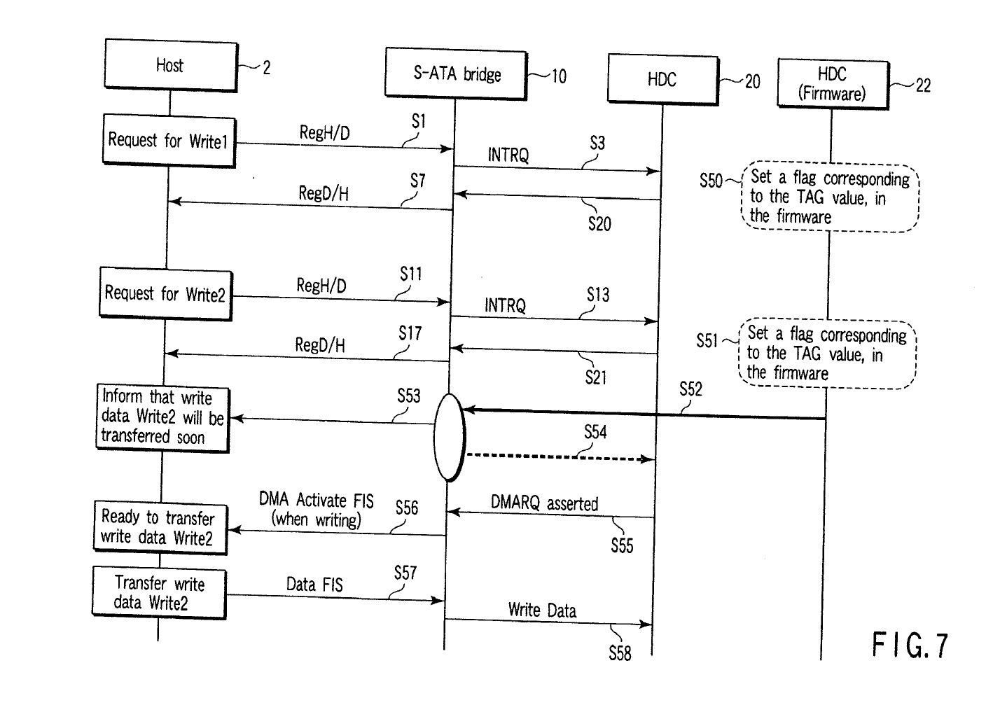

FIGS. 5 and 6 are timing charts explaining, respectively, two methods of processing a read command in the present embodiment. FIGS. 7 and. 8 are timing charts explaining, respectively, two methods of processing a write command in the present embodiment.

The sequence of processing read commands will be explained, with reference to FIGS. 5 and 6. Assume that the host system 2 issues two read commands, or read requests Read1 and Read2, one after another.

Note that Steps S1, S3 and S7 (FIG. 5) correspond to Steps S1, S3 and S7 shown in FIG. 4, respectively. First, the host system 2 transmits RegH/D (register FIS), or read request Read1, to the S-ATA bridge 10 (Step S1). In the S-ATA bridge 10, the read request Read1 is stored into the shadow register 11, and the S-ATA bridge 10 outputs an interruption signal INTRQ to the HDC 20 (Step S3). The HDC 20 accesses the buffer memory 12 that stores all contents of the shadow register 11 (Step S20). In the meantime, the FW 22 of the HDC 20 sets a flag that corresponds to the TAG value (Step S22).

After checking the TAG number and LBA address of the command, the S-ATA bridge 10 sets the busy bit to 0, and then outputs RegD/H, or a response, to the host system 2 (Step S7). The process of receiving a command thus ends in the S-ATA bridge 10.

The host system 2 then transmits RegH/D, or read request Read2, to the S-ATA bridge 10 (Step S11). In the S-ATA bridge 10, the read request Read2 is stored into the shadow register 11. Then, the S-ATA bridge 10 outputs signal INTRQ to the HDC 20 (Step S13). The HDC 20 accesses the buffer memory that stores all contents of the shadow register 11 (Step S21). In the HDC 20, the FW 22 sets a flag that corresponds to the TAG value (Step S23). The S-ATA bridge 10 outputs RegD/H, or a response, to the host system 2 (Step S17).

Upon receiving all these commands, the S-ATA bridge 10 starts the process of transferring data that has been read in accordance with read requests Read1 and Read2.

First, the FW 22 of the HDC 20 transmits the TAG value, BufferOfset, TransferCount and START=1 (trigger) to the S-ATA bridge 10 (Step S24). Upon receiving these data items, the S-ATA bridge 10 transmits DAM setup FIS to the host system 2, information that read data Read2 will be soon transmitted in accordance with the read request Rread2 (Step S25).

The S-ATA bridge 10 transmits a Service command to the HDC 20 (Step S26). At this time, DAM setup FIS may collide in the next queuing command Red Arrow. If this happens, the FW 22 sets the TAG value again. The service command uses the legacy-command queuing protocol as pseudo-protocol. Upon receiving the service command, the HDC 20 transmits DMARQ asserted to the S-ATA bridge 10 (Step S27).

Next, as shown in FIG. 6, the HDC 20 transmits the read data to the S-ATA bridge 10 (Step S28). Upon receiving the read data, the S-ATA bridge 10 transmits Data FIS to the host system 2, transferring read data Read2 to the host system 2 (Step S29). The FW 22 of the HDC 20 sets a flag for any command executed, and transmits the flag to the S-ATA bridge 10 (Step S30). The HDC 20 transmits signal INTRQ indicating that the completion of data transfer, to the S-ATA bridge 10 (Step S31). Upon receiving these data items, the S-ATA bridge 10 transmits Set Device Bits FIS (bit5 clear) to the host system 2, terminating the transfer of read data Read2 (Step S32).

The FW 22 transmits the TAG value, BufferOfset, TransferCount and START=1 (trigger) to the S-ATA bridge 10 (Step S33). Upon receiving these data items, the S-ATA bridge 10 transmits DAM setup FIS to the host system 2, information that read data Read1 will be soon transmitted in accordance with the read request Rread2 (Step S34). The S-ATA bridge 10 then transmits Service command to the HDC 20 (Step S35). Upon receiving Service command, the HDC 20 transmits DMARQ asserted to the S-ATA bridge 10 (Step S36). The HDC 20 transmits the read data to the S-ATA bridge 10 (Step S37).

Upon receiving the read data, the S-ATA bridge 10 transmits Data FIS to the host system 2, transferring read data Read1 to the host system 2 (Step S38). The FW 22 of the HDC 20 sets a flag for any command executed, and transmits the flag to the S-ATA bridge 10 (Step S39). The HDC 20 transmits signal INTRQ indicating that the completion of data transfer, to the S-ATA bridge 10 (Step S40). Upon receiving these data items, the S-ATA bridge 10 transmits Set Device Bits FIS (bit5 clear) to the host system 2, terminating the transfer of read data Read1 (Step S41).

When an error is made, the host system 2 transmits a READ LOG EXT command to the S-ATA bridge 10 (Step S43). Upon receiving the READ LOG EXT command, the S-ATA bridge 10 transmits this command, READ LOG EXT, to the HDC 20 (Step S42). The S-ATA bridge 10 then transmits Set Device Bits FIS (all bit clear) to the host system 2 (Step S44).

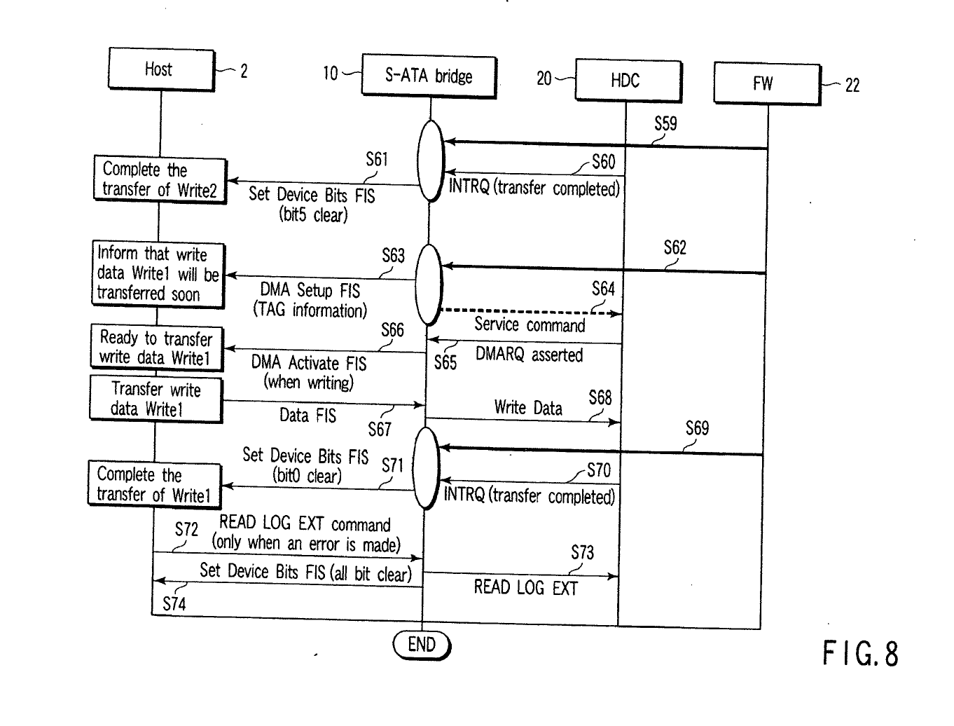

The sequence of processing write commands will be explained, with reference to FIGS. 7 and 8. The sequence of processing write commands is similar to the sequence of processing read commands. Assume that the host system 2 issues two write commands, or write requests Write1 and Write, one after another.

Note that Steps S1, S3 and S7 (FIG. 7) correspond to Steps S1, S3 and S7 shown in FIG. 4, respectively. First, the host system 2 transmits RegH/D (register FIS), or write request Write1, to the S-ATA bridge 10 (Step S1). In the S-ATA bridge 10, the write request Write1 is stored into the shadow register 11, and the S-ATA bridge 10 outputs signal INTRQ to the HDC 20 (Step S3). The HDC 20 accesses the buffer memory 12 that stores all contents of the shadow register 11 (Step S20). In the meantime, the FW 22 of the HDC 20 sets a flag that corresponds to the TAG value (Step S50).

After checking the TAG number and LBA address of the command, the S-ATA bridge 10 sets the busy bit to 0, and then outputs RegD/H, or a response, to the host system 2 (Step S7). The process of receiving a command thus ends in the S-ATA bridge 10.

The host system 2 then transmits RegH/D, or write request Write2, to the S-ATA bridge 10 (Step S11). In the S-ATA bridge 10, the write request Write2 is stored into the shadow register 11. Then, the S-ATA bridge 10 outputs signal INTRQ to the HDC 20 (Step S13). The HDC 20 accesses the buffer memory 12 that stores all contents of the shadow register 11 (Step S21). In the HDC 20, the FW 22 sets a flag that corresponds to the TAG value (Step S51). The S-ATA bridge 10 outputs RegD/H, or a response, to the host system 2 (Step S17).

Upon receiving all these commands, the S-ATA bridge 10 starts the process of transferring data that has been written in accordance with write requests Write1 and Write2.

First, the FW 22 of the HDC 20 transmits the TAG value, BufferOfset, TransferCount and START=1 (trigger) to the S-ATA bridge 10 (Step S52). Upon receiving these data items, the S-ATA bridge 10 transmits DAM setup FIS to the host system 2, information that write data Write2 will be soon transmitted in accordance with the read request Rread2 (Step S35).

The S-ATA bridge 10 transmits a Service command to the HDC 20 (Step S54). At this time, DAM setup FIS may collide in the next queuing command Red Arrow. If this happens, the FW 22 sets the TAG value again. The service command uses the legacy-command queuing protocol as pseudo-protocol. Upon receiving the service command, the HDC 20 transmits DMARQ asserted to the S-ATA bridge 10 (Step S55).

Upon receiving DMARQ asserted, the S-ATA bridge 10 transmits DMA Active FIS to the host system 2 (Step S56). Upon receipt of DMA Active FIS, the host system 2 transmits Data FIS to the S-ATA bridge 10 (Step S57). Upon receiving Data FIS, the S-ATA bridge 10 transmits write data to the HDC 20 (Step S58).

Next, as shown in FIG. 8, the FW 22 of the HDC 20 sets a flag for any command executed, and transmits the flag to the S-ATA bridge 10 (Step S59). The HDC 20 transmits signal INTRQ indicating that the completion of data transfer, to the S-ATA bridge 10 (Step S60). Upon receiving these data items, the S-ATA bridge 10 transmits Set Device Bits FIS (bit5 clear) to the host system 2, terminating the transfer of write data Read2 (Step S61).

The FW 22 transmits the TAG value, BufferOfset, TransferCount and START=1 (trigger) to the S-ATA bridge 10 (Step S62). Upon receiving these data items, the S-ATA bridge 10 transmits DAM setup FIS to the host system 2, information that write data will be soon transmitted in accordance with the read request Rread2 (Step S63). The S-ATA bridge 10 then transmits Service command to the HDC 20 (Step S64). Upon receiving Service command, the HDC 20 transmits DMARQ asserted to the S-ATA bridge 10 (Step S65).

Upon receiving DMARQ asserted, the S-ATA bridge 10 transmits DMA Active FIS to the host system 2 (Step S66). Upon receiving DMA Active, the host system 2 transmits Data FIS to the S-ATA bridge 10 (Step S67). Upon receipt of Data FIS, the S-ATA bridge 10 transmits write data to the HDC 20 (Step S68).

The FW 22 of the HDC 20 sets a flag for any command executed, and transmits the flag to the S-ATA bridge 10 (Step S69). The HDC 20 transmits signal INTRQ indicating that the completion of data transfer, to the S-ATA bridge 10 (Step S70). Upon receiving these data items, the S-ATA bridge 10 transmits Set Device Bits FIS (bit5 clear) to the host system 2, terminating the transfer of read data Read1 (Step S71).

When an error is made, the host system 2 transmits a READ LOG EXT command to the S-ATA bridge 10 (Step S72). Upon receiving the READ LOG EXT command, the S-ATA bridge 10 transmits this command, READ LOG EXT, to the HDC 20 (Step S73). The S-ATA bridge 10 then transmits Set Device Bits FIS (all bit clear) to the host system 2 (Step S74).

Thus, the serial ATA interface 1, which is composed of the S-ATA bridge 10 and the HDC 20, can process the read commands and write commands transmitted from the host system 2.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A serial ATA interface apparatus for connecting a host system and a device, comprising:
a register which stores commands transmitted from the host system via a serial ATA bus;
a transmission unit which transmits an interruption signal to a controller provided in the device through a parallel ATA bus, said interruption signal being stored in the register and indicating that the transmission unit has received a command;
a memory which stores the commands transferred from the register and which can be accessed by the controller; and
an output unit which checks the commands stored in the register and which outputs a response signal to the host system through the serial ATA bus when the commands are found to be correct.

2. The apparatus according to claim 1, wherein the device is a disk drive which records and reproduces data on and from a disk, the controller is a disk controller which functions as an interface in the disk drive and which is connected to the parallel ATA bus, and the transfer of the commands and data between the disk controller and the host system through the serial bus ATA is controlled.

3. The apparatus according to claim 1, wherein the controller has a task file register which stores the commands supplied from the host system, and accesses the commands stored in the memory and stores the commands into the task file register, in accordance with the interruption signal.

4. The apparatus according to claim 1, wherein the register stores a plurality of commands sequentially sent from the host system through the serial ATA bus; and the output unit is configured to output response signals for the commands, respectively, to the host system through the serial ATA bus.

5. A disk drive to be connected to a host system by a serial ATA interface and configured to record data on, or reproduce data from, a disk-shaped medium in response to commands supplied from the host system, said disk drive comprising;
a disk controller which executes the command supplied from ht host system, thereby to control data transfer between the disk-shaped medium and the host system; and
a serial ATA bridge which is connected to the host system by the serial ATA bus and connected to the disk controller by a parallel ATA bus and which comprises;
a register which stores commands sent from the host system through the serial ATA bus;
a transmission unit which transmits an interruption signal to the disk controller through the parallel ATA bus, said interruption signal indicating that the transmission unit has received a command;
a memory which stores the commands transferred from the register and which can be accessed by the disk controller; and
an output unit which checks the commands stored in the register and which outputs a response signal to the host system through the serial ATA bus when the commands are found to be correct.

6. The disk drive according to claim 5, wherein the disk controller has a task file register which stores the commands supplied from the host system, and accesses the commands stored in the memory and stores the commands into the task file register, in accordance with the interruption signal.

7. The disk drive according to claim 5, wherein the register stores a plurality of commands sequentially sent from the host system through the serial ATA bus; and the output unit is configured to output response signals for the commands, respectively, to the host system through the serial ATA bus.

8. The disk drive according to claim 5, wherein the serial ATA bridge includes means for checking commands to manage data transfer corresponding to the commands, before the disk controller executes the commands in an random order.

9. The disk drive according to claim 5, wherein the disk controller and the serial ATA bridge are provided in one integrated circuit element and connected by the parallel ATA bus.

10. A method of controlling a serial ATA interface for connecting a host system and a device, the method comprising:
storing commands sent from the host system through a serial ATA bus, into a register;
transmitting an interruption signal to a controller through the parallel ATA bus, said interruption signal indicating that the register has received the commands;
storing the commands transferred from the register, into a memory which can be accessed by the controller;
checking the commands stored in the register; and
outputting a response signal to the host system through the serial ATA bus when the commands are found to be correct.
